(19) United States
(12) Patent Application Publication
(10) Pub. No.: US 2025/0248176 A1
(43) Pub. Date: Jul. 31, 2025

(54) LIGHT EMITTING ELEMENT AND DISPLAY DEVICE INCLUDING THE SAME

(71) Applicant: Samsung Display Co., LTD., Yongin-si (KR)

(72) Inventors: Tae Hee LEE, Yongin-si (KR); Byoung Yong KIM, Yongin-si (KR); Jae Gwang UM, Yongin-si (KR); Moon Won CHANG, Yongin-si (KR)

(73) Assignee: Samsung Display Co., LTD., Yongin-si (KR)

(21) Appl. No.: 18/804,830

(22) Filed: Aug. 14, 2024

(30) Foreign Application Priority Data
Jan. 31, 2024 (KR) 10-2024-0015232

(51) Int. Cl. H01L 33/24; H01L 25/075; H01L 33/02; H01L 33/62

(52) U.S. Cl. CPC H10H 20/821; H01L 25/0753; H10H 20/8215; H10H 20/857

(57) ABSTRACT

A light emitting element includes a bonding electrode, and a light emitting stack including a first semiconductor layer, an active layer, and a second semiconductor layer sequentially disposed each other on the bonding electrode. At least one protrusion structure is defined on an upper surface of the light emitting stack, and the protrusion structure includes a first protrusion protruding in a direction away from the bonding electrode and defining a groove concave in a direction facing the bonding electrode, and a second protrusion protruding in a direction away from the bonding electrode in the groove of the first protrusion.

### CROSS-REFERENCE TO RELATED APPLICATIONS

This application claims priority to and benefits of Korean Patent Application No. 10-2024-0015232 under 35 U.S.C. § 119, filed on Jan. 31, 2024 in the Korean Intellectual Property Office, the entire contents of which are incorporated herein by reference.

### BACKGROUND

### 1. Technical Field

The disclosure relates to a light emitting element and a display device including the same.

### 2. Description of the Related Art

A display device includes light emitting elements emitting light. The display device displays an image by combining the light emitted from the light emitting elements.

Each of the light emitting elements may be aligned (or disposed) at a preset position in the display device. In case that an alignment of the light emitting elements is defective, display quality of the display device may be deteriorated.

In case that emission efficiency of the light emitting element is improved, display quality of the display device may also be improved.

### SUMMARY

An object of the disclosure is to provide a light emitting element capable of improving display quality, and a display device including the same.

According to embodiments of the disclosure, a light emitting element may include a bonding electrode, and a light emitting stack including a first semiconductor layer, an active layer, and a second semiconductor layer sequentially disposed each other on the bonding electrode. At least one protrusion structure may be defined on an upper surface of the light emitting stack, and the protrusion structure may include a first protrusion protruding in a direction away from the bonding electrode and defining a groove concave in a direction facing the bonding electrode, and a second protrusion protruding in a direction away from the bonding electrode in the groove of the first protrusion.

In an embodiment, the second protrusion may be spaced apart from an inner surface of the first protrusion defining the groove.

In an embodiment, the second protrusion may include a (2-1)-th protrusion having a height about equal to a depth of the groove, and a (2-2)-th protrusion disposed on the (2-1)-th protrusion.

In an embodiment, the (2-2)-th protrusion may have a substantially cone shape.

In an embodiment, the protrusion structure and the second semiconductor layer may be integral.

In an embodiment, the first protrusion and the second protrusion may be integral.

In an embodiment, the protrusion structure may include a first protrusion structure disposed at a center of the upper surface of the light emitting stack in a plan view.

In an embodiment, the protrusion structure may include a plurality of second protrusion structures, and the plurality of second protrusion structures may be disposed symmetrically with respect to a center of the upper surface of the light emitting stack in a plan view.

In an embodiment, the first semiconductor layer may have a first polarity, and the second semiconductor layer may have a second polarity different from the first polarity.

In an embodiment, the second semiconductor layer may include a first doping portion and a second doping portion sequentially defined on the active layer, and a first average doping concentration of a dopant in the first doping portion may be greater than a second average doping concentration of a dopant in the second doping portion.

According to embodiments of the disclosure, a display device may include a light emitting element connected between an anode electrode and a cathode electrode. The light emitting element may include a bonding electrode, and a light emitting stack including a first semiconductor layer, an active layer, and a second semiconductor layer sequentially disposed each other on the bonding electrode. At least one protrusion structure may be defined on an upper surface of the light emitting stack, and the protrusion structure may include a first protrusion protruding in a direction away from the bonding electrode and defining a groove concave in a direction facing the bonding electrode, and a second protrusion protruding in a direction away from the bonding electrode in the groove of the first protrusion.

In an embodiment, the second protrusion may be spaced apart from an inner surface of the first protrusion defining the groove.

In an embodiment, the second protrusion may include a (2-1)-th protrusion having a height about equal to a depth of the groove, and a (2-2)-th protrusion disposed on the (2-1)-th protrusion.

In an embodiment, the (2-2)-th protrusion may have a substantially cone shape.

In an embodiment, the protrusion structure and the second semiconductor layer may be integral.

In an embodiment, the first protrusion and the second protrusion may be integral.

In an embodiment, the protrusion structure may include a first protrusion structure disposed at a center of the upper surface of the light emitting stack in a plan view.

In an embodiment, the protrusion structure may include a plurality of second protrusion structures, and the plurality of second protrusion structures may be disposed symmetrically with respect to a center of the upper surface of the light emitting stack in a plan view.

In an embodiment, the bonding electrode may be disposed on the anode electrode and may be electrically connected to the anode electrode.

In an embodiment, the cathode electrode may be disposed on the anode electrode to face the anode electrode, and may cover the upper surface of the light emitting stack defining the protrusion structure.

In the light emitting element according to embodiments of the disclosure, the protrusion structure defined on the upper surface of the light emitting stack may include the first protrusion protruding in the direction away from the bonding electrode and defining the groove concave in the direction facing the bonding electrode, and the second protrusion protruding in the direction away from the bonding electrode in the groove of the first protrusion.

The display device according to embodiments of the disclosure may include the light emitting element.

The protrusion structure may provide sufficient fixing force to an adhesive layer in case that transporting the light emitting element. Therefore, alignment reliability of the light emitting element may be improved, and display quality of the display device may be improved.

An uneven structure defined by the protrusion structure may improve light output efficiency by changing a critical angle of light emitted from the light emitting element. Accordingly, display quality of the display device may be improved.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### BRIEF DESCRIPTION OF THE DRAWINGS

The above and other features of the disclosure will become more apparent by describing in further detail embodiments thereof with reference to the accompanying drawings, in which:

FIG. 1 is a block diagram illustrating a display device according to embodiments;

FIG. 2 is a block diagram illustrating one sub-pixel among sub-pixels included in the display device of FIG. 1;

FIG. 3 is a schematic plan view illustrating a display panel configuring the display device of FIG. 1;

FIG. 4 is a schematic cross-sectional view illustrating an embodiment of a display panel of FIG. 3;

FIG. 5 is a schematic cross-sectional view illustrating an embodiment of the display panel of FIG. 3;

FIG. 6 is a schematic plan view illustrating a first embodiment of a light emitting element included in the sub-pixel of FIG. 3;

FIG. 7 is a schematic cross-sectional view taken along line X1-X1′ of FIG. 6;

FIG. 8 is a schematic plan view illustrating a second embodiment of the light emitting element included in the sub-pixel of FIG. 3;

FIG. 9 is a schematic cross-sectional view taken along line X2-X2′ of FIG. 8;

FIG. 10 is a schematic plan view illustrating a third embodiment of the light emitting element included in the sub-pixel of FIG. 3;

FIG. 11 is a schematic plan view illustrating a fourth embodiment of the light emitting element included in the sub-pixel of FIG. 3;

FIG. 12 is a schematic cross-sectional view taken along line X3-X3′ of FIG. 11;

FIG. 13 is a schematic plan view illustrating a fifth embodiment of the light emitting element included in the sub-pixel of FIG. 3;

FIG. 14 is a schematic cross-sectional view illustrating a method of providing a light emitting element according to embodiments;

FIG. 15 is a schematic plan view illustrating an example of one of the pixels included in the display panel of FIG. 3;

FIG. 16 is a schematic cross-sectional view taken along line X4-X4′ of FIG. 15;

FIG. 17 is a block diagram illustrating a display system according to an embodiment; and

FIGS. 18 to 21 are schematic perspective views illustrating application examples of the display system of FIG. 17.

### DETAILED DESCRIPTION OF THE EMBODIMENTS

Hereinafter, embodiments are described in detail with reference to the accompanying drawings. It should be noted that in the following description, portions for understanding an operation according to the disclosure are described, and descriptions of other portions may be omitted in order not to obscure the subject matter of the disclosure. The disclosure may be embodied in other forms without being limited to the embodiments described herein. However, the embodiments described herein are provided to describe in detail to readily implement the technical spirit of the disclosure to those skilled in the art to which the disclosure belongs.

Throughout the specification, in a case where a portion is “connected” to another portion, the case includes not only a case where the portion is “directly connected” but also a case where the portion is “indirectly connected” with another element disposed therebetween. Terms used herein are for describing embodiments and are not intended to limit the disclosure.

Throughout the specification, in a case where a given portion “includes”, the case means that the portion may further include another component without excluding another component unless otherwise stated.

“At least any one of X, Y, and Z” and “at least any one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Here, terms such as first and second may be used to describe various components, but these components are not limited to these terms. These terms are used to distinguish one component from another component. Therefore, a first component may refer to a second component in a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions of on and under. The device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown given shapes, and should be interpreted as including, for example, changes in shapes that occur as a result of manufacturing. As described above, the shapes shown in the drawings may not show actual shapes of areas of a device, and the embodiments are not limited thereto.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

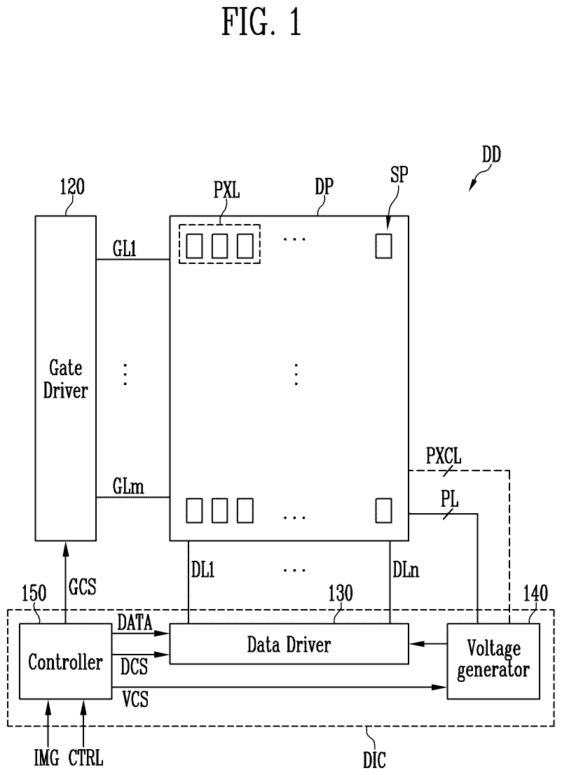

FIG. 1 is a block diagram illustrating a display device according to embodiments.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate of light of two or more colors. For example, each of the sub-pixels SP may generate light such as red, green, blue, cyan, magenta, or yellow.

Two or more sub-pixels among the sub-pixels SP may configure one pixel PXL. For example, the pixel PXL may include three sub-pixels as shown in FIG. 1. The pixel PXL may emit light of various colors and various luminances according to a combination of light emitted from the sub-pixels included in the pixel PXL.

The gate driver 120 may be connected to the sub-pixels SP arranged or disposed in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal, and the like within the spirit and the scope of the disclosure.

The gate driver 120 may be disposed on one side or a side of the display panel DP. However, embodiments are not limited thereto. For example, the gate driver 120 may be divided into two or more physically and/or logically divided drivers, and such drivers may be disposed on one side or a side of the display panel DP and another side of the display panel DP opposite the one side or a side. As described above, the gate driver 120 may be disposed around the display panel DP in various shapes according to embodiments.

The data driver 130 is connected to the sub-pixels SP arranged or disposed in a column direction through the first to n-th data lines DL1 to DLn. The data driver 130 receives image data DATA and a data control signal DCS from the controller 150. The data driver 130 operates in response to the data control signal DCS. In embodiments, the data control signal DCS may include a source start signal, a source shift clock, a source output enable signal, and the like within the spirit and the scope of the disclosure.

The data driver 130 may receive voltages from the voltage generator 140. The data driver 130 may apply data signals having grayscale voltages corresponding to the image data DATA to the first to n-th data lines DL1 to DLn using the received voltages. In case that the gate signal is applied to each of the first to m-th gate lines GL1 to GLm, the data signals corresponding to the image data DATA may be applied to the data lines DL1 to DLn. Accordingly, the sub-pixels SP may generate light corresponding to the data signals, and the display panel DP may display an image.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate voltages and provide the generated voltages to components of the display device DD, such as the gate driver 120, the data driver 130, and the controller 150. The voltage generator 140 may generate the voltages by receiving an input voltage from an outside of the display device DD and regulating the received voltage.

The voltage generator 140 may generate a first power voltage and a second power voltage. The generated first and second power voltages may be provided to the sub-pixels SP through power lines PL. In an embodiment, at least one of the first and second power voltages may be provided from the outside of the display device DD.

The voltage generator 140 may provide various voltages and/or signals. For example, the voltage generator 140 may provide one or more initialization voltages applied to the sub-pixels SP. For example, during a sensing operation for sensing electrical characteristics of transistors and/or light emitting elements of the sub-pixels SP, a selectable reference voltage may be applied to the first to n-th data lines DL1 to DLn, and the voltage generator 140 may generate the reference voltage and transmit the reference voltage to the data driver 130. For example, during a display operation for displaying an image on the display panel DP, common pixel control signals may be applied to the sub-pixels SP, and the voltage generator 140 may generate the pixel control signals. In embodiments, the voltage generator 140 may provide the pixel control signals to the sub-pixels SP through pixel control lines PXCL. In FIG. 1, the pixel control lines PXCL are connected between the voltage generator 140 and the display panel DP, but embodiments are not limited thereto. For example, the pixel control lines PXCL may be connected between the gate driver 120 and the display panel DP. In this case, the pixel control signals may be transmitted from the voltage generator 140 to the pixel control lines PXCL through the gate driver 120.

The controller 150 controls overall operations of the display device DD. The controller 150 receives input image data IMG and a control signal CTRL corresponding thereto from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device DD or the display panel DP and output the image data DATA. In embodiments, the controller 150 may output the image data DATA by aligning the input image data IMG so that the input image data IMG is suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. In other embodiments, at least one of the data driver 130, the voltage generator 140, and the controller 150 may be provided as a component distinguished from the driver integrated circuit DIC.

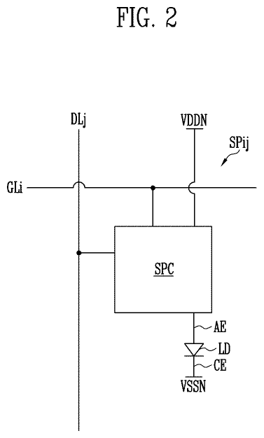

FIG. 2 is a block diagram illustrating one sub-pixel among the sub-pixels included in the display device of FIG. 1. In FIG. 2, among the sub-pixels SP of FIG. 1, a sub-pixel SPij arranged or disposed in an i-th row (i is an integer greater than or equal to 1 and less than or equal to m) and a j-th column (j is an integer greater than or equal to 1 and less than or equal to n) is shown as an example.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL of FIG. 1 and may receive the first power voltage. The second power voltage node VSSN may be connected to another one of the power lines PL of FIG. 1 and may receive the second power voltage. The first power voltage may have a level higher than that of the second power voltage.

The light emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD is configured to emit light according to a current flowing from the anode electrode AE to the cathode electrode CE.

The sub-pixel circuit SPC may be connected to an i-th gate line GLi among the first to m-th gate lines GL1 to GLm of FIG. 1, and a j-th data line DLj among the first to n-th data lines DL1 to DLn of FIG. 1. In response to a gate signal received through the i-th gate line GLi, the sub-pixel circuit SPC may control the light emitting element LD to emit light according to a data signal received through the j-th data line DLj. In embodiments, the sub-pixel circuit SPC may be further connected to the pixel control lines PXCL of FIG. 1. In this case, the sub-pixel circuit SPC may control the light emitting element LD in further response to the pixel control signals received through the pixel control lines PXCL.

For such operations, the sub-pixel circuit SPC may include circuit elements, for example, transistors and one or more capacitors.

The transistors of the sub-pixel circuit SPC may include P-type transistors and/or N-type transistors. In embodiments, the transistors of the sub-pixel circuit SPC may include a metal oxide semiconductor field effect transistor (MOSFET). In embodiments, the transistors of the sub-pixel circuit SPC may include an amorphous silicon semiconductor, a monocrystalline silicon semiconductor, a polycrystalline silicon semiconductor, an oxide semiconductor, and the like within the spirit and the scope of the disclosure.

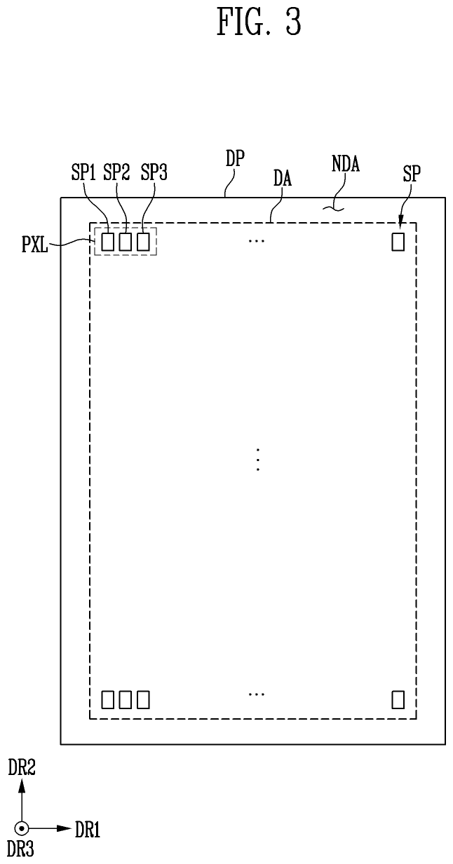

FIG. 3 is a schematic plan view illustrating the display panel configuring the display device of FIG. 1.

Referring to FIG. 3, the display panel DP may include a display area DA and a non-display area NDA. The display panel DP may display an image through the display area DA. The non-display area NDA may be disposed around the display area DA.

The display panel DP may include the sub-pixels SP disposed in the display area DA. The sub-pixels SP may be arranged or disposed along a first direction DR1 and a second direction DR2 crossing (or intersecting) the first direction DR1. For example, the sub-pixels SP may be arranged or disposed in a matrix form along the first direction DR1 and the second direction DR2. As another example, the sub-pixels SP may be arranged or disposed in a zigzag form along the first direction DR1 and the second direction DR2. An arrangement of the sub-pixels SP may vary according to embodiments. The first direction DR1 may be a row direction, and the second direction DR2 may be a column direction.

Two or more sub-pixels among the sub-pixels SP may configure one pixel PXL. In FIG. 3, the pixel PXL includes three sub-pixels SP1, SP2, and SP3, but embodiments are not limited thereto. For example, the pixel PXL may include two sub-pixels. Hereinafter, for convenience of description, it is assumed that the pixel PXL includes the first to third sub-pixels SP1, SP2, and SP3.

Each of the first to third sub-pixels SP1, SP2, and SP3 may generate light of one of various colors such as red, green, blue, cyan, magenta, and yellow. Hereinafter, for clear and concise description, it is assumed that the first sub-pixel SP1 is configured to generate light of a red color, the second sub-pixel SP2 is configured to generate light of a green color, and the third sub-pixel SP3 is configured to generate light of a blue color.

Each of the first to third sub-pixels SP1, SP2, and SP3 may include at least one light emitting element configured to generate light. In embodiments, the light emitting elements of the first to third sub-pixels SP1, SP2, and SP3 may generate light of the same color. For example, the light emitting elements of the first to third sub-pixels SP1, SP2, and SP3 may generate the light of the blue color. In other embodiments, the light emitting elements of the first to third sub-pixels SP1, SP2, and SP3 may generate light of different colors. For example, the light emitting elements of the first to third sub-pixels SP1, SP2, and SP3 may generate light of a red color, a green color, and a blue color, respectively.

As the display panel DP, a light emitting diode display panel (LED display panel) using a micro scale or nano scale of light emitting diode as a light emitting element, and a display panel capable of self-emission such as an organic light emitting display panel (OLED panel) using an organic light emitting diode as a light emitting element may be used.

A component for controlling the sub-pixels SP may be disposed in the non-display area NDA. Lines connected to the sub-pixels SP, for example, the first to m-th gate lines GL1 to GLm of FIG. 1, the first to n-th data lines DL1 to DLn, the power lines PL, and the pixel control lines PXCL may be disposed in the non-display area NDA.

At least one of the gate driver 120, the data driver 130, the voltage generator 140, and the controller 150 of FIG. 1 may be disposed in the non-display area NDA of the display panel DP. In embodiments, the gate driver 120 may be disposed in the non-display area NDA. In this case, the data driver 130, the voltage generator 140, and the controller 150 may be implemented as a driver integrated circuit DIC of FIG. 1, separate from the display panel DP, and the driver integrated circuit DIC may be connected to the lines disposed in the non-display area NDA. In other embodiments, the gate driver 120 may be implemented as one integrated circuit separate from the display panel DP, together with the data driver 130, the voltage generator 140, and the controller 150.

In embodiments, the display area DA may have various shapes. The display area DA may have a closed loop shape including sides of a straight line and/or a curved line. For example, the display area DA may have shapes of a polygon, a circle, a semicircle, an ellipse, and the like within the spirit and the scope of the disclosure.

In embodiments, the display panel DP may have a flat display surface. In other embodiments, the display panel DP may have a display surface that is at least partially round. In embodiments, the display panel DP may be bendable, foldable, or rollable. In such cases, the display panel DP and/or a substrate of the display panel DP may include materials having a flexible property.

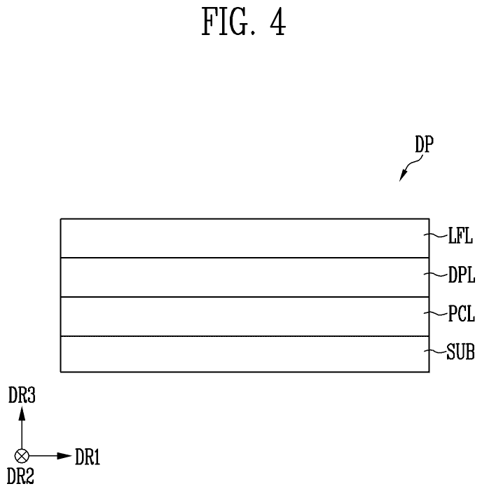

FIG. 4 is a schematic cross-sectional view illustrating an embodiment of the display panel of FIG. 3.

Referring to FIG. 4, the display panel DP may include a substrate SUB, and a pixel circuit layer PCL, a display element layer DPL, and a light functional layer LFL sequentially stacked on the substrate SUB in a third direction DR3 crossing (or intersecting) the first and second directions DR1 and DR2.

The substrate SUB may be formed of an insulating material such as glass or resin. For example, the substrate SUB may include a glass substrate. As another example, the substrate SUB may include a polyimide (PI) substrate. As another example, the substrate SUB may include a silicon wafer substrate formed using a semiconductor process.

In embodiments, the substrate SUB may be formed of a flexible material that may be bent or folded, and may have a single-layer structure or a multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers and semiconductor patterns and conductive patterns disposed between the insulating layers. The conductive patterns of the pixel circuit layer PCL may function as circuit elements, lines, and the like within the spirit and the scope of the disclosure.

The circuit elements of the pixel circuit layer PCL may form the sub-pixel circuit SPC of each of the sub-pixels SP of FIG. 3. In other words, the circuit elements of the pixel circuit layer PCL may be provided as transistors and one or more capacitors of the sub-pixel circuit SPC.

The lines of the pixel circuit layer PCL may include lines connected to the sub-pixels SP. The lines of the pixel circuit layer PCL may include various signal lines and/or voltage lines that to drive the display element layer DPL.

The display element layer DPL may be disposed on the pixel circuit layer PCL. The display element layer DPL may include light emitting elements of the sub-pixels SP.

The light functional layer LFL may be disposed on the display element layer DPL. The light functional layer LFL may include light conversion patterns having color conversion particles and/or scattering particles. For example, the color conversion particles may include quantum dots. The quantum dots may change a wavelength (or color) of light emitted from the display element layer DPL. The light functional layer LFL may further include light scattering patterns having the scattering particles. In embodiments, the light conversion patterns and the light scattering patterns may be omitted.

The light functional layer LFL may further include a color filter layer including color filters. The color filter may selectively transmit light of a given wavelength (or a given color). In embodiments, the color filter layer may be omitted.

A window for protecting an exposure surface (or an upper surface) of the display panel DP may be provided on the light functional layer LFL. The window may protect the display panel DP from external shock. The window may be coupled or connected to the light functional layer LFL through an optically transparent adhesive (or cohesive) member. The window may have a multi-layer structure selected from a glass substrate, a plastic film, and a plastic substrate. The multi-layer structure may be formed through a continuous process or an adhesion process using an adhesive layer. All or a portion of the window may be flexible.

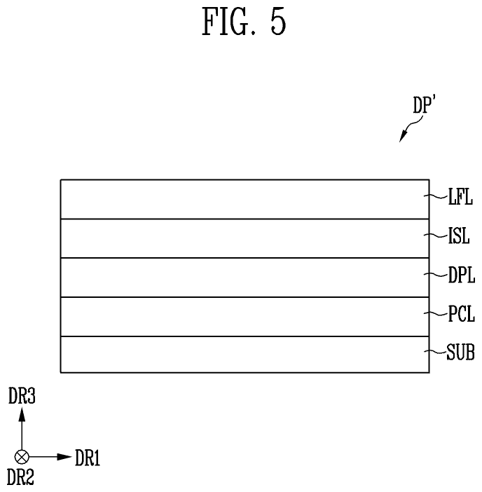

FIG. 5 is a schematic cross-sectional view illustrating an embodiment of the display panel of FIG. 3.

Referring to FIG. 5, the display panel DP′ may include the substrate SUB, the pixel circuit layer PCL, the display element layer DPL, an input sensing layer ISL, and the light functional layer LFL. The substrate SUB, the pixel circuit layer PCL, the display element layer DPL, and the light functional layer LFL may be configured equally (or similarly) to the substrate SUB, the pixel circuit layer PCL, the display element layer DPL, and the light functional layer LFL described with reference to FIG. 4. Therefore, a description of an overlapping content may be omitted.

The input sensing layer ISL may sense a user's input on an upper surface (or a display surface) of the display panel DP′. The input sensing layer ISL may include components suitable for sensing an external object such as a user's hand, or a pen. For example, the input sensing layer ISL may include touch electrodes.

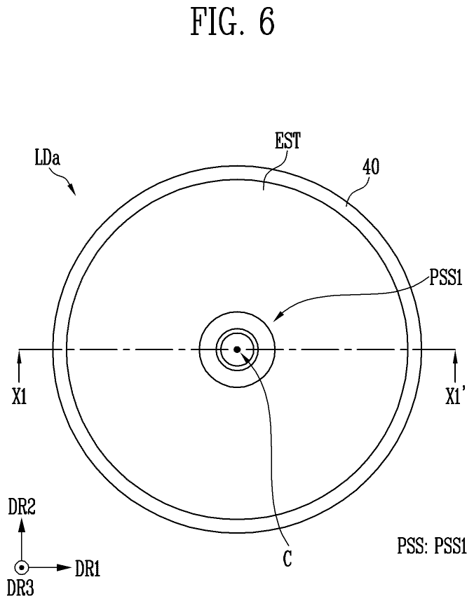

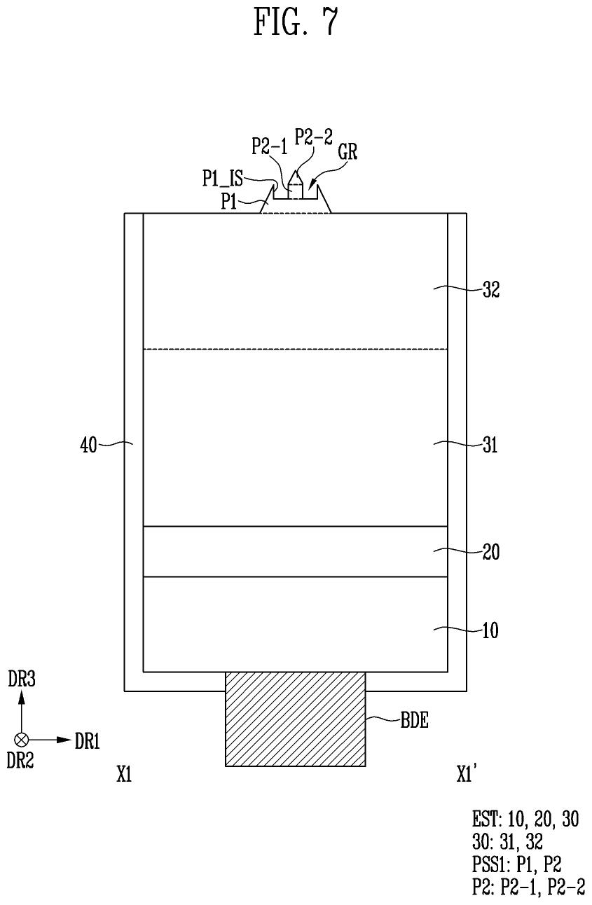

FIG. 6 is a schematic plan view illustrating a first embodiment of the light emitting element included in the sub-pixel of FIG. 3. FIG. 7 is a schematic cross-sectional view taken along line X1-X1′ of FIG. 6.

Referring to FIGS. 6 and 7, the light emitting element LDa may include a bonding electrode BDE, a light emitting stack EST, and an insulating layer 40. The light emitting stack EST may include a first semiconductor layer 10, an active layer 20, and a second semiconductor layer 30. The light emitting element LDa may be implemented as a vertical light emitting stack in which the bonding electrode BDE, the first semiconductor layer 10, the active layer 20, and the second semiconductor layer 30 may be sequentially stacked each other along the third direction DR3.

The first semiconductor layer 10 is configured to provide a hole. The first semiconductor layer 10 may have a first polarity. For example, the first semiconductor layer 10 may include at least one p-type semiconductor layer. For example, the first semiconductor layer 10 may include at least one semiconductor material among gallium nitride (GaN), aluminum gallium nitride (AlGaN), indium gallium nitride (InGaN), aluminum nitride (AlN), and indium nitride (InN), and may be a p-type semiconductor layer doped with a first conductive dopant (or a p-type dopant), such as magnesium (Mg), zinc (Zn), calcium (Ca), strontium (Sr), and barium (Ba). However, a material configuring the first semiconductor layer 10 is not limited thereto, and various other materials may configure the first semiconductor layer 10. In an embodiment, the first semiconductor layer 10 may include a gallium nitride (GaN) semiconductor material doped with the first conductive dopant (or the p-type dopant).

The second semiconductor layer 30 may be disposed on the first semiconductor layer 10 and may be configured to provide an electron. The second semiconductor layer 30 may have a second polarity different from the first polarity. For example, the second semiconductor layer 30 may include at least one n-type semiconductor layer. For example, the second semiconductor layer 30 may include one semiconductor material among gallium nitride (GaN), aluminum gallium nitride (AlGaN), indium gallium nitride (InGaN), aluminum nitride (AlN), and indium nitride (InN), and may be an n-type semiconductor layer doped with a second conductive dopant (or an n-type dopant) such as silicon (Si), germanium (Ge), and tin (Sn). However, a material configuring the second semiconductor layer 30 is not limited thereto, and various other materials may configure the second semiconductor layer 30. In an embodiment, the second semiconductor layer 30 may include a gallium nitride (GaN) semiconductor material doped with the second conductive dopant (or the n-type dopant.

In embodiments, the second semiconductor layer 30 may include a first doping portion 31 and a second doping portion 32 in an order along the third direction DR3. The first doping portion 31 may be an area in which a dopant is doped at a relatively high concentration, and the second doping portion 32 may be an area where a dopant is doped at a relatively low concentration of the dopant is not substantially doped. For example, a first average doping concentration of the dopant in the first doping portion 31 may be greater than a second average doping concentration of the dopant in the second doping portion 32.

The active layer 20 may be disposed between the first semiconductor layer 10 and the second semiconductor layer 30 and may provide an area where the electron and the hole are recombined. As the electron and the hole recombine in the active layer 20, the electron and the hole may transit to a lower energy level, and thus light having a wavelength corresponding thereto may be generated. The active layer 20 may be formed as a single or multiple quantum wells structure. In case that the active layer 20 is formed as the multiple quantum wells structure, a unit including a barrier layer, a strain reinforcing layer, and a well layer may be repeatedly stacked each other to form the active layer 20. However, the active layer 20 is not limited to the above-described structure.

The bonding electrode BDE may be disposed under (or below) the first semiconductor layer 10. The bonding electrode BDE may be electrically connected to the first semiconductor layer 10. The bonding electrode BDE may include a eutectic metal.

In embodiments, a reflective electrode may be further disposed between the bonding electrode BDE and the first semiconductor layer 10. In this case, light output efficiency of light emitted from the light emitting element LDa may be improved. The reflective electrode may be formed of a conductive material having a selectable reflectance. The conductive material may include an opaque metal. The opaque metal may include, for example, a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and an alloy thereof. However, a material of the reflective electrode is not limited thereto.

The insulating layer 40 may cover a portion of an outer peripheral surface of the light emitting stack EST. For example, the insulating layer 40 may cover a portion of a side surface of the light emitting stack EST and a portion of a lower surface of the light emitting stack EST. In this case, the insulating layer 40 may cover at least a side surface of the active layer 20. The insulating layer 40 may serve to prevent an electrical short circuit that may occur in case that the active layer 20 comes into contact with a conductive material other than the first and second semiconductor layers 10 and 30. In embodiments, the insulating layer 40 may be configured to expose an upper surface of the light emitting stack EST.

In embodiments, at least one protrusion structure PSS may be defined on the upper surface of the light emitting stack EST. For example, the protrusion structure PSS may include a first protrusion structure PSS1.

The protrusion structure PSS may include a first protrusion P1 and a second protrusion P2. The first protrusion P1 may protrude in a direction away from the bonding electrode BDE (for example, the third direction DR3). The first protrusion P1 may define a groove GR concave in a direction facing the bonding electrode BDE (for example, a direction opposite to the third direction DR3). The second protrusion P2 may protrude in a direction away from the bonding electrode BDE in the groove GR.

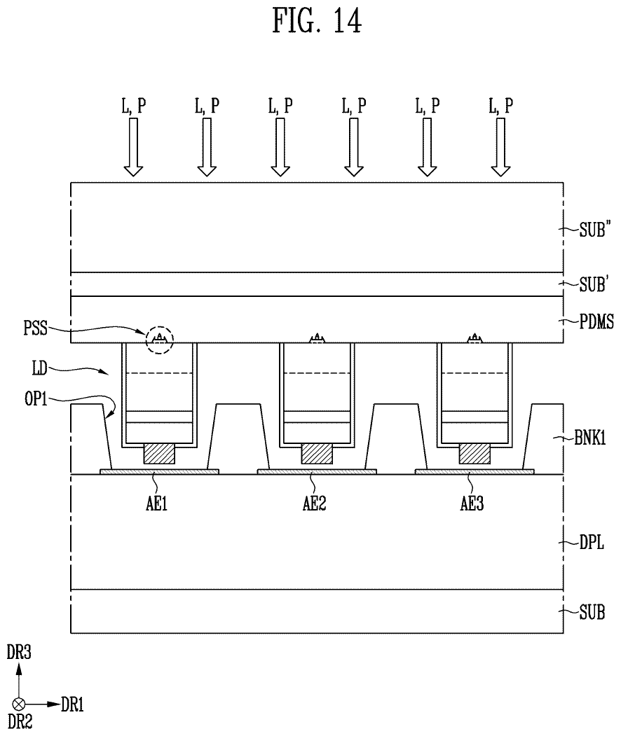

In embodiments, the second protrusion P2 may be configured to be spaced apart from an inner surface P1_IS of the first protrusion P1 defining the groove GR. For example, the second protrusion P2 may be surrounded by the inner surface P1_IS of the first protrusion P1 in the groove GR. Accordingly, a separation space may be formed between the second protrusion P2 and the inner surface P1_IS of the first protrusion P1. The separation space may serve to provide fixing force in case that the protrusion structure PSS is embedded in an adhesive layer PDMS (refer to FIG. 14) of a transfer substrate SUB′ (refer to FIG. 14) described later.

In embodiments, the second protrusion P2 may include a (2-1)-th protrusion P2-1 having a height equal to a depth of the groove GR and a (2-2)-th protrusion P2-2 disposed on the (2-1)-th protrusion P2-1. The (2-1)-th protrusion P2-1 and the (2-2)-th protrusion P2-2 may have various shapes that may provide greater fixing force to the adhesive layer PDMS (refer to FIG. 14) described later. For example, the (2-1)-th protrusion P2-1 may have a cylindrical shape. For example, the (2-2)-th protrusion P2-2 may have a cone shape.

In embodiments, the protrusion structure PSS may be integral with the second semiconductor layer 30. For example, the protrusion structure PSS may be integral with the second doping portion 32. In this case, the first protrusion P1 and the second protrusion P2 may be integral, and the (2-1)-th protrusion P2-1 and the (2-2)-th protrusion P2-2 may be integral. For example, the first protrusion P1, the (2-1)-th protrusion P2-1, and the (2-2)-th protrusion P2-2 may be integral with the second doping portion 32.

In an embodiment, the first protrusion structure PSS1 may be disposed at a center of the upper surface of the light emitting stack EST in a plan view as shown in FIG. 6. Accordingly, the light emitting element LDa fixed to the adhesive layer PDMS (refer to FIG. 14) of the transfer substrate SUB′ (refer to FIG. 14) described later may be prevented from being tilted in a given direction.

In FIG. 6, the upper surface of the light emitting stack EST is circular, but the disclosure is not limited thereto. The upper surface of the light emitting stack EST may be configured of various shapes having a closed curve shape.

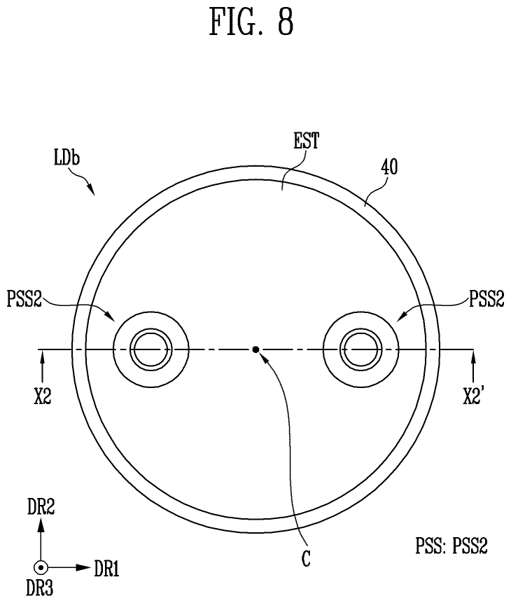

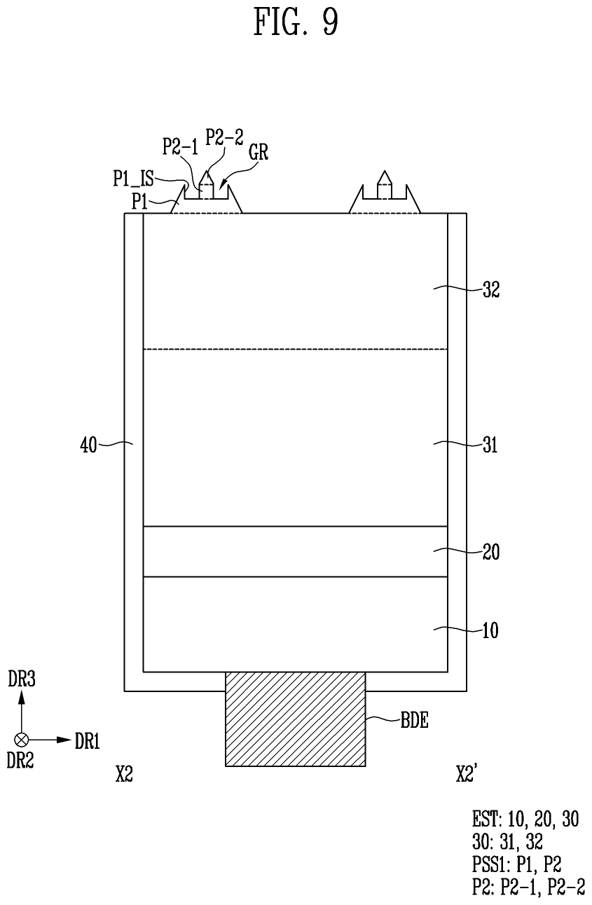

FIG. 8 is a schematic plan view illustrating a second embodiment of the light emitting element included in the sub-pixel of FIG. 3. FIG. 9 is a schematic cross-sectional view taken along line X2-X2′ of FIG. 8.

Hereinafter, the disclosure is described based on a difference of a light emitting element LDb compared to the light emitting element LDa described with reference to FIGS. 6 and 7, and a part omitted from the description is replaced with the content described above.

Referring to FIGS. 8 and 9, the protrusion structure PSS may include two second protrusion structures PSS2. Each of the two second protrusion structures PSS2 may be configured substantially the same as the first protrusion structure PSS1 described with reference to FIGS. 6 and 7.

As shown in FIG. 8, the two second protrusion structures PSS2 may be disposed symmetrically with respect to the center C of the upper surface of the light emitting stack EST in a plan view. Accordingly, the light emitting element LDb fixed to the adhesive layer PDMS (refer to FIG. 14) of the transfer substrate SUB′ (refer to FIG. 14) described later may be prevented from being tilted in a given direction.

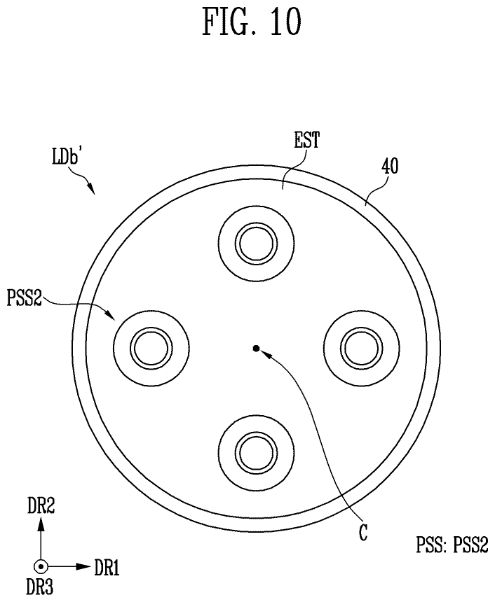

FIG. 10 is a schematic plan view illustrating a third embodiment of the light emitting element included in the sub-pixel of FIG. 3.

Hereinafter, a disclosure is described based on a difference of a light emitting element LDb′ compared to the light emitting element LDb described with reference to FIGS. 8 and 9, and a part omitted from the description is replaced with the content described above.

Referring to FIG. 10, the protrusion structure PSS may include four second protrusion structures PSS2. Each of the four second protrusion structures PSS2 may be configured substantially the same as the first protrusion structure PSS1 described with reference to FIGS. 6 and 7.

As shown in FIG. 10, the four second protrusion structures PSS2 may be disposed symmetrically with respect to the center C of the upper surface of the light emitting stack EST in a plan view. Accordingly, the light emitting element LDb′ fixed to the adhesive layer PDMS (refer to FIG. 14) of the transfer substrate SUB′ (refer to FIG. 14) described later may be prevented from being tilted in a given direction.

Referring to FIGS. 8 to 10, the number of second protrusion structures PSS2 is not limited by the above description. For example, in a range that may prevent tilting of the light emitting element fixed to the adhesive layer PDMS (refer to FIG. 14) of the transfer substrate SUB′ (refer to FIG. 14) described later, the number of second protrusion structures PSS2 may be variously changed. For example, six, eight, or more second protrusion structures PSS2 may be provided.

In this case, as the number of protrusion structures PSS increases, the fixing force of the light emitting element to the adhesive layer PDMS (refer to FIG. 14) of the transfer substrate SUB′ (refer to FIG. 14) may be improved. As the number of protrusion structures PSS increases, a critical angle of light may change due to an uneven structure formed on an upper surface of the light emitting element, and thus light output efficiency of the light emitting element may be improved.

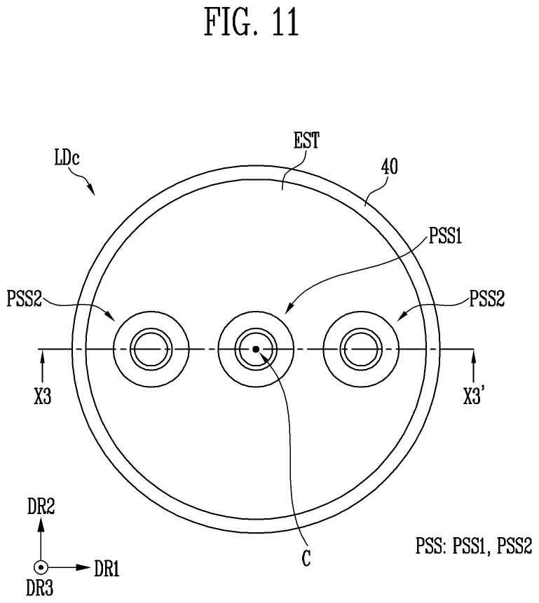

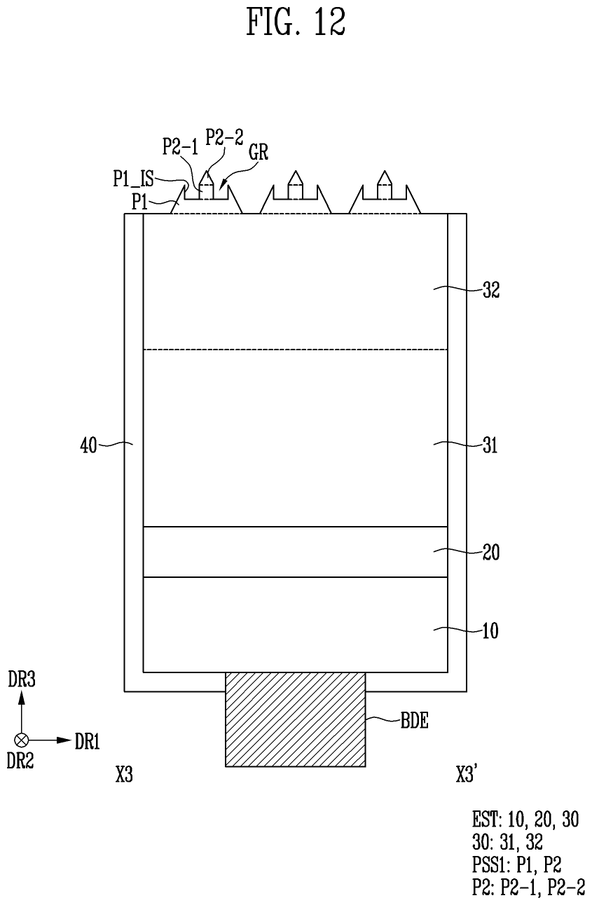

FIG. 11 is a schematic plan view illustrating a fourth embodiment of the light emitting element included in the sub-pixel of FIG. 3. FIG. 12 is a schematic cross-sectional view taken along line X3-X3′ of FIG. 11.

Hereinafter, the disclosure is described based on a difference of a light emitting element LDc compared to the light emitting element LDa described with reference to FIGS. 6 and 7 and the light emitting element LDb described with reference to FIGS. 8 and 9, and a part omitted from the description is replaced with the content described above.

Referring to FIGS. 11 and 12, the protrusion structure PSS may include a first protrusion structure PSS1 and two second protrusion structures PSS2. Accordingly, the light emitting element LDc fixed to the adhesive layer PDMS (refer to FIG. 14) of the transfer substrate SUB′ (refer to FIG. 14) described later may be more effectively prevented from being tilted in a given direction.

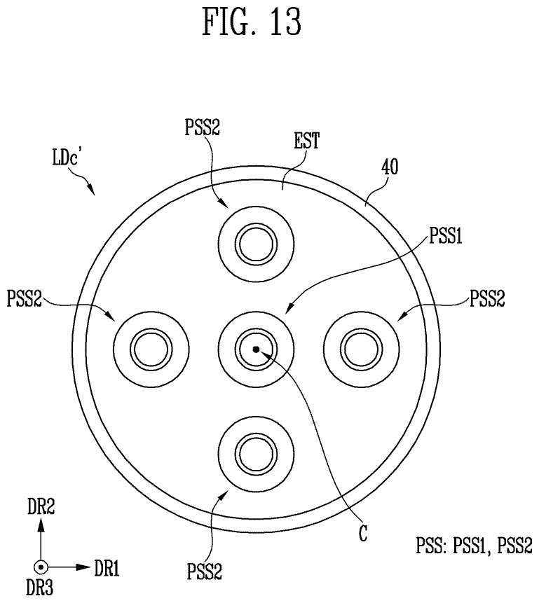

FIG. 13 is a schematic plan view illustrating a fifth embodiment of the light emitting element included in the sub-pixel of FIG. 3.

Hereinafter, the disclosure is described based on a difference of a light emitting element LDc′ compared to the light emitting element LDa described with reference to FIGS. 6 and 7 and the light emitting element LDb′ described with reference to FIG. 10, and a part omitted from description is replaced with the content described above.

Referring to FIG. 13, the protrusion structure PSS may include a first protrusion structure PSS1 and four second protrusion structures PSS2. Accordingly, the light emitting element LDc′ fixed to the adhesive layer PDMS (refer to FIG. 14) of the transfer substrate SUB′ (refer to FIG. 14) described later may be more effectively prevented from being tilted in a given direction.

Referring to FIGS. 11 to 13, the number of second protrusion structures PSS2 is not limited by the above description. For example, six, eight, or more second protrusion structures PSS2 may be provided. In this case, as the number of protrusion structures PSS increases, fixing force of the light emitting element to the adhesive layer PDMS (refer to FIG. 14) of the transfer substrate SUB′ (refer to FIG. 14) may be improved, and light output efficiency of the light emitting element may be improved.

FIG. 14 is a schematic cross-sectional view illustrating a method of providing a light emitting element according to embodiments.

Referring to FIG. 14, the light emitting element LD of which manufacturing is completed may be fixed to the adhesive layer PDMS formed on one surface or a surface of the transfer substrate SUB′ and may be transported. Here, the light emitting element LD may be one of the light emitting elements LDa, LDb, LDb′, LDc, and LDc′ described with reference to FIGS. 6 to 13.

The protrusion structure PSS of the light emitting element LD may be embedded in the adhesive layer PDMS. Accordingly, the light emitting element LD may be more effectively fixed to the adhesive layer PDMS. Tilting of the light emitting element LD may be effectively prevented.

The transfer substrate SUB′ may be aligned to face the display element layer DPL formed on the substrate SUB. In detail, the light emitting element LD embedded in the adhesive layer PDMS may be aligned to face first to third anode electrodes AE1, AE2, and AE3 formed on the display element layer DPL. In this case, components such as a first bank BNK1 that exposes portions of the first to third anode electrodes AE1, AE2, and AE3 may be additionally formed on the display element layer DPL.

A bonding substrate SUB″ may be provided on the transfer substrate SUB′. The bonding substrate SUB″ may be, for example, a quartz substrate. Laser L may be irradiated to the bonding substrate SUB″. Pressure P may be applied to the transfer substrate SUB′ in a direction facing the display element layer DPL (for example, the direction opposite to the third direction DR3) through the bonding substrate SUB″. Accordingly, heat and pressure causing the bonding electrode BDE of the light emitting element LD to be bonded to the first to third anode electrodes AE1, AE2, and AE3 may be provided.

After the bonding electrode BDE is bonded to the first to third anode electrodes AE1, AE2, and AE3, the transfer substrate SUB′ and the adhesive layer PDMS provided on one surface or a surface of the transfer substrate SUB′ may be removed. Accordingly, the light emitting element LD bonded to the first to third anode electrodes AE1, AE2, and AE3 may be provided.

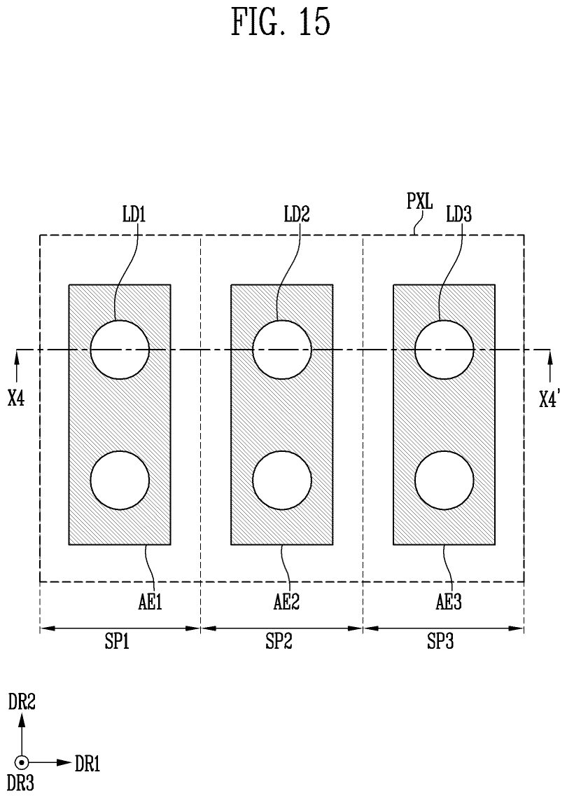

FIG. 15 is a schematic plan view illustrating an embodiment of one of the pixels included in the display panel of FIG. 3.

Referring to FIG. 15, the pixel PXL may include the first to third sub-pixels SP1, SP2, and SP3. The first to third sub-pixels SP1, SP2, and SP3 may be arranged or disposed in the first direction DR1. However, an arrangement of the pixel PXL is not limited thereto and may variously change according to embodiments. For example, the first to third sub-pixels SP1, SP2, and SP3 may be arranged or disposed in a zigzag.

First to third anode electrodes AE1, AE2, and AE3 may be disposed in the first to third sub-pixels SP1, SP2, and SP3, respectively. The first anode electrode AE1 may be provided as the anode electrode AE included in the sub-pixel circuit SPC (refer to FIG. 2) of the first sub-pixel SP1. The second anode electrode AE2 may be provided as the anode electrode AE included in the sub-pixel circuit SPC of the second sub-pixel SP2. The third anode electrode AE3 may be provided as the anode electrode AE included in the sub-pixel circuit SPC of the third sub-pixel SP3.

One or more first light emitting elements LD1, one or more second light emitting elements LD2, and one or more third light emitting elements LD3 may be disposed on the first to third anode electrodes AE1, AE2, and AE3. The first light emitting elements LD1 may be connected to the first anode electrode AE1. The second light emitting elements LD2 may be connected to the second anode electrode AE2. The third light emitting elements LD3 may be connected to the third anode electrode AE3. In case that light emitting elements are provided in each sub-pixel, each anode electrode may have a shape extending in a given direction such as the second direction DR2, and light emitting elements connected thereto may be arranged or disposed in the same direction.

The first light emitting elements LD1 may be provided as the light emitting element LD (refer to FIG. 2) included in the first sub-pixel SP1. The second light emitting elements LD2 may be provided as the light emitting element LD (refer to FIG. 2) included in the second sub-pixel SP2. The third light emitting elements LD3 may be provided as the light emitting element LD (refer to FIG. 2) included in the third sub-pixel SP3. In case that light emitting elements are provided in one sub-pixel, the light emitting elements may be connected in parallel between the anode electrode and the cathode electrode and may be provided as the light emitting element LD of FIG. 2.

Each of the first light emitting elements LD1, the second light emitting elements LD2, and the third light emitting elements LD3 may be one of the light emitting elements LDa, LDb, LDb′ LDc, and LDc′ described with reference to FIGS. 6 to 13.

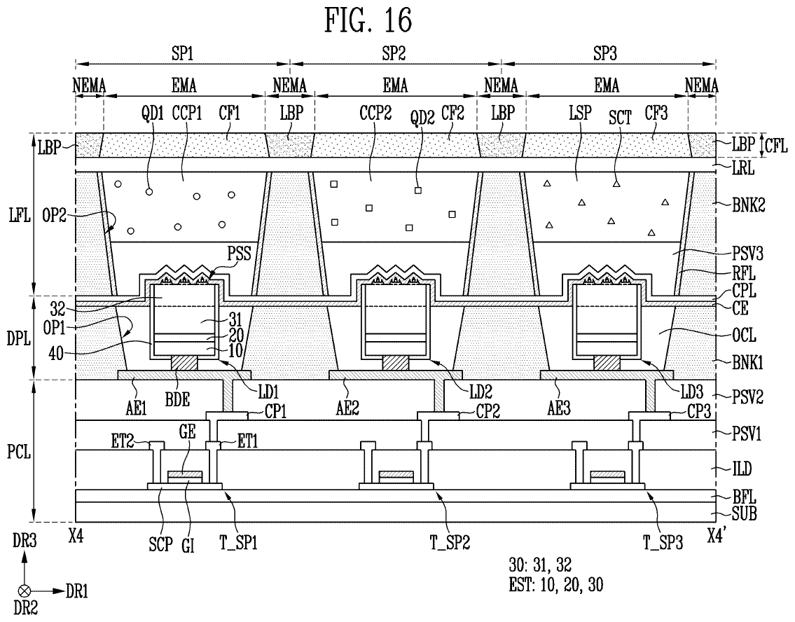

FIG. 16 is a schematic cross-sectional view taken along line X4-X4′ of FIG. 15.

Referring to FIGS. 15 and 16, the pixel circuit layer PCL, the display element layer DPL, and the light functional layer LFL may be sequentially disposed on the substrate SUB.

The pixel circuit layer PCL may include insulating layers, semiconductor patterns, and conductive patterns stacked each other on the substrate SUB. The insulating layers may include a buffer layer BFL, one or more interlayer insulating layers ILD, and one or more passivation layers PSV1 and PSV2. The semiconductor patterns and the conductive patterns may be positioned between the insulating layers. The conductive patterns may include at least one material among copper (Cu), molybdenum (Mo), tungsten (W), aluminum neodymium (AlNd), titanium (Ti), aluminum (Al), and silver (Ag).

As described with reference to FIG. 2, the sub-pixel circuit SPC (refer to FIG. 2) of each of the first to third sub-pixels SP1, SP2, and SP3 may include transistors and one or more capacitors. The semiconductor patterns and the conductive patterns of the pixel circuit layer PCL may function as the transistors and the capacitors of the sub-pixel circuit SPC. The conductive patterns of the pixel circuit layer PCL may further functions as the lines, for example, the first to m-th gate lines GL1 to GLm, the first to n-th data lines DL1 to DLn, the power lines PL, and the pixel control lines PXCL of FIG. 1.

The buffer layer BFL may be disposed on one surface or a surface of the substrate SUB. The buffer layer BFL may prevent an impurity from diffusing into the circuit elements and the lines included in the pixel circuit layer PCL. The buffer layer BFL may include an inorganic insulating layer including an inorganic material. In embodiments, the buffer layer BFL may include at least one of metal oxides such as silicon nitride, silicon oxide, silicon oxynitride, and aluminum oxide. The buffer layer BFL may be provided as a single layer or multiple layers. In case that the buffer layer BFL is provided as the multiple layers, each layer may be formed of a same material or may be formed of different materials.

In embodiments, one or more barrier layers may be disposed between the substrate SUB and the buffer layer BFL. Each of the barrier layers may include polyimide.

First to third transistors T_SP1, T_SP2, and T_SP3 respectively corresponding to the first to third sub-pixels SP1, SP2, and SP3 may be disposed on the buffer layer BFL. The first transistor T_SP1 may be one of the transistors of the sub-pixel circuit SPC included in the first sub-pixel SP1. The second transistor T_SP2 may be one of the transistors of the sub-pixel circuit SPC included in the second sub-pixel SP2. The third transistor T_SP3 may be one of the transistors of the sub-pixel circuit SPC included in the third sub-pixel SP3. Each of the first to third transistors T_SP1, T_SP2, and T_SP3 may be understood as a transistor connected to the anode electrode among the transistors of the corresponding sub-pixel.

The first transistor T_SP1 may include a semiconductor pattern SCP, a gate electrode GE, a first terminal ET1, and a second terminal ET2. The first terminal ET1 may be one of a source electrode and a drain electrode, and the second terminal ET2 may be the other one of the source electrode and the drain electrode. For example, the first terminal ET1 may be the source electrode, and the second terminal ET2 may be the drain electrode.

The semiconductor pattern SCP may be disposed on the buffer layer BFL. The semiconductor pattern SCP may include a first contact area contacting the first terminal ET1 and a second contact area contacting the second terminal ET2. An area between the first contact area and the second contact area may be a channel area. The channel area may overlap the gate electrode GE of the first transistor T_SP1. The channel area may be a semiconductor pattern that is not substantially doped with an impurity and may be an intrinsic semiconductor. The first contact area and the second contact area may be a semiconductor pattern doped with an impurity. As the impurity, for example, a p-type impurity may be used, but embodiments are not limited thereto.

The semiconductor pattern SCP may include one of various types of semiconductors, for example, an amorphous silicon semiconductor, a monocrystalline silicon semiconductor, a polycrystalline silicon semiconductor, a low temperature poly silicon semiconductor, and an oxide semiconductor.

The interlayer insulating layers ILD sequentially stacked each other may be disposed on the semiconductor pattern SCP. The interlayer insulating layers ILD may be inorganic insulating layers including an inorganic material. For example, each of the interlayer insulating layers ILD may include at least one of metal oxides such as silicon nitride, silicon oxide, silicon oxynitride, and aluminum oxide. However, the interlayer insulating layers ILD are not limited thereto. For example, one of the interlayer insulating layers ILD may include an organic insulating layer including an organic material.

The interlayer insulating layers ILD may electrically separate conductive patterns and/or semiconductor patterns disposed between the interlayer insulating layers ILD from each other. For example, the interlayer insulating layers ILD may include a gate insulating layer GI disposed on the semiconductor pattern SCP. The gate insulating layer GI may be disposed between the semiconductor pattern SCP and the gate electrode GE so that the semiconductor pattern SCP is spaced apart from the gate electrode GE. In embodiments, the gate insulating layer GI may be provided entirely on the semiconductor pattern SCP and the buffer layer BFL to cover the semiconductor pattern SCP and the buffer layer BFL. As the number of layers required to form the conductive patterns and/or the semiconductor patterns increases, the number of interlayer insulating layers ILD may increase.

The gate electrode GE may be disposed on the gate insulating layer GI. The gate electrode GE may overlap the channel area of the semiconductor pattern SCP. In embodiments, the gate electrode GE may be provided as a single layer including at least one material among copper (Cu), molybdenum (Mo), tungsten (W), aluminum neodymium (AlNd), titanium (Ti), aluminum (Al), and silver (Ag). In embodiments, the gate electrode GE may be provided as multiple layers including at least one material among molybdenum (Mo), titanium (Ti), copper (Cu), aluminum (Al), and silver (Ag), which are low-resistance materials.

The first and second terminals ET1 and ET2 may be disposed on the interlayer insulating layers ILD. The first and second terminals ET1 and ET2 may contact the semiconductor pattern SCP through contact holes passing through the interlayer insulating layers ILD. The first and second terminals ET1 and ET2 may respectively contact the first and second contact areas of the semiconductor pattern SCP. Each of the first and second terminals ET1 and ET2 may include at least one material among copper (Cu), molybdenum (Mo), tungsten (W), aluminum neodymium (AlNd), titanium (Ti), aluminum (Al), and silver (Ag).

Although the first and second terminals ET1 and ET2 are shown as separate electrodes electrically connected to the semiconductor pattern SCP, embodiments are not limited thereto. In embodiments, the first terminal ET1 may be a first contact area adjacent to one side or a side of the channel area of the semiconductor pattern SCP, and the second terminal ET2 may be a second contact area adjacent to another side of the channel area. In this case, the first terminal ET1 may be electrically connected to the light emitting element LD through a connection means such as a bridge electrode disposed on at least one of the interlayer insulating layers ILD.

In embodiments, the first transistor T_SP1 may be configured of a low-temperature polysilicon transistor. However, embodiments are not limited thereto. For example, the first transistor T_SP1 may be configured of an oxide semiconductor transistor. In embodiments, the sub-pixel circuit of each sub-pixel may include different types of transistors. For example, the first transistor T_SP1 may be configured of a low-temperature polysilicon transistor, and another transistor included in the sub-pixel circuit SPC of the first sub-pixel SP1 may be configured of an oxide semiconductor transistor. In this case, the oxide semiconductor of the corresponding oxide semiconductor transistor may be disposed on one of the interlayer insulating layers ILD rather than the insulating layer on which the semiconductor pattern SCP of the first transistor T_SP1 is disposed.

In embodiments, a case where the first transistor T_SP1 is a transistor of a top gate structure is described as an example, but embodiments are not limited thereto. For example, the first transistor T_SP1 may be a transistor of a bottom gate structure. A structure of the first transistor T_SP1 may be variously changed.

Each of the second and third transistors T_SP2 and T_SP3 may be configured similarly to the first transistor T_SP1. Therefore, a description of an overlapping content may be omitted.

At least some of the various lines of the display panel DP and/or the display device DD may be further disposed on the interlayer insulating layers ILD.

The first passivation layer PSV1 may be disposed on the interlayer insulating layers ILD and the first and second terminals ET1 and ET2. A passivation layer may be referred to as a protective layer or a via layer. The first passivation layer PSV1 may protect components disposed under (or below) the first passivation layer PSV1 and may provide a flat upper surface.

First to third connection patterns CP1, CP2, and CP3 may be disposed on the first passivation layer PSV1. The first to third connection patterns CP1, CP2, and CP3 may be respectively connect to the first terminals ET1 of the first to third transistors T_SP1, T_SP2, and T_SP3 by passing through the first passivation layer PSV1. The first to third connection patterns CP1, CP2, and CP3 may include at least one material among copper (Cu), molybdenum (Mo), tungsten (W), aluminum neodymium (AlNd), titanium (Ti), aluminum (Al), and silver (Ag).

At least some of the various lines of the display panel DP and/or the display device DD may be further disposed on the first passivation layer PSV1.

The second passivation layer PSV2 may be disposed on the first to third connection patterns CP1, CP2, and CP3 and the first passivation layer PSV1. The second passivation layer PSV2 may protect components disposed under (or below) the second passivation layer PSV2 and may provide a flat upper surface.

Each of the first and second passivation layers PSV1 and PSV2 may include an inorganic insulating layer including an inorganic material and/or an organic insulating layer including an organic material. The inorganic insulating layer may include, for example, at least one of metal oxides such as silicon oxide, silicon nitride, silicon oxynitride, and aluminum oxide. The organic insulating layer may include, for example, at least one of acrylic resin, epoxy resin, phenol resin, polyamide resin, polyimide resin, unsaturated polyester resin, poly-phenylene ether resin, poly-phenylene sulfide resin, and benzocyclobutene resin.

The first and second passivation layers PSV1 and PSV2 may include a same material as one of the interlayer insulating layers ILD, but embodiments are not limited thereto. Each of the first and second passivation layers PSV1 and PSV2 may be provided as a single layer, but may also be provided as multiple layers.

The display element layer DPL may be disposed on the second passivation layer PSV2. The display element layer DPL may include the first to third anode electrodes AE1, AE2, and AE3, the first bank BNK1, the first to third light emitting elements LD1, LD2, and LD3, an overcoat layer OCL, the cathode electrode CE, and a capping layer CPL.

The first to third anode electrodes AE1, AE2, and AE3 may be disposed in the first to third sub-pixels SP1, SP2, and SP3, respectively, on the pixel circuit layer PCL.

The first anode electrode AE1 may be electrically connected to the first connection pattern CP1 through a contact hole passing through the second passivation layer PSV2. The second anode electrode AE2 may be electrically connected to the second connection pattern CP2 through another contact hole passing through the second passivation layer PSV2. The third anode electrode AE3 may be electrically connected to the third connection pattern CP3 through still another contact hole passing through the second passivation layer PSV2. As described above, the first to third anode electrodes AE1, AE2, and AE3 may be electrically connected to the first to third transistors T_SP1, T_SP2, and T_SP3, respectively.

The first bank BNK1 may be disposed on the first to third anode electrodes AE1, AE2, and AE3. The first bank BNK1 may have first openings OP1 exposing portions of the first to third anode electrodes AE1, AE2, and AE3. The first to third light emitting elements LD1, LD2, and LD3 may be disposed in the first openings OP1 of the first bank BNK1. As described above, the first bank BNK1 may be provided as a pixel defining layer that defines areas where the first to third light emitting elements LD1, LD2, and LD3 are positioned.

The first bank BNK1 may be configured to include a light blocking material to prevent light mixing between adjacent sub-pixels. In embodiments, the first bank BNK1 may include an organic material. For example, the first bank BNK1 may include an organic insulating material such as acryl resin, epoxy resin, phenol resin, polyamide resin, and polyimide resin. According to embodiments, in order to further improve light output efficiency, a reflective layer including a reflective material may be further disposed on a side surface of the first bank BNK1 adjacent to the first openings OP1.

The first to third light emitting elements LD1, LD2, and LD3 may be disposed on the first to third anode electrodes AE1, AE2, and AE3, respectively. The first to third light emitting elements LD1, LD2, and LD3 may be bonded and coupled or connected to the first to third anode electrodes AE1, AE2, and AE3, respectively. Each of the first to third light emitting elements LD1, LD2, and LD3 may be one of the light emitting elements LDa, LDb, LDb′, LDc, and LDc′ described with reference to FIGS. 6 to 13. Therefore, a description of an overlapping content may be omitted.

The bonding electrode BDE of the first light emitting element LD1 may be connected to the first anode electrode AE1. A bonding electrode of the second light emitting element LD2 may be connected to the second anode electrode AE2. A bonding electrode of the third light emitting element LD3 may be connected to the third anode electrode AE3. An upper surface of the second semiconductor layers 30 of the first to third light emitting elements LD1, LD2, and LD3 may be connected to the cathode electrode CE. Accordingly, the first light emitting element LD1 may be connected between the first anode electrode AE1 and the cathode electrode CE, the second light emitting element LD2 may be connected between the second anode electrode AE2 and the cathode electrode CE, and the third light emitting element LD3 may be connected between the third anode electrode AE3 and the cathode electrode CE.

The overcoat layer OCL may be disposed in the first openings OP1 where the first to third light emitting elements LD1, LD2, and LD3 are disposed. The overcoat layer OCL may fix the first to third light emitting elements LD1, LD2, and LD3 bonded to the first to third anode electrodes AE1, AE2, and AE3 so that the first to third light emitting elements LD1, LD2, and LD3 do not move. The overcoat layer OCL may protect configurations disposed under (or below) the overcoat layer OCL from a foreign substance such as dust and moisture. The overcoat layer OCL may include at least one of an inorganic insulating layer and an organic insulating layer. For example, the overcoat layer OCL may include epoxy, but embodiments are not limited thereto.

In embodiments, the overcoat layer OCL may not be disposed on an upper surface of the first to third light emitting elements LD1, LD2, and LD3. The first to third light emitting elements LD1, LD2, and LD3 may protrude into the light functional layer LFL. The first to third light emitting elements LD1, LD2, and LD3 may be at least partially positioned in second openings OP2 of a second bank BNK2. For example, a height of the upper surface of each of the first to third light emitting elements LD1, LD2, and LD3 from the substrate SUB may be higher than the lowest end of a reflective layer RFL. Accordingly, light emitted from the first to third light emitting elements LD1, LD2, and LD3 may be provided to the light functional layer LFL at a relatively high rate.

The cathode electrode CE may be disposed on the first to third light emitting elements LD1, LD2, and LD3. The cathode electrode CE may be entirely disposed on the first bank BNK1, the first to third light emitting elements LD1, LD2, and LD3, and the overcoat layer OCL. The cathode electrode CE may contact an upper surface of the second semiconductor layer 30 of each of the first to third light emitting elements LD1, LD2, and LD3 and a reflective electrode layer 60. In this case, the cathode electrode CE may entirely cover the protrusion structures PSS of the first to third light emitting elements LD1, LD2, and LD3. The cathode electrode CE may be electrically connected to the second power voltage node VSSN of FIG. 2. The second power voltage applied to the second power voltage node VSSN may be transmitted to the first to third light emitting elements LD1, LD2, and LD3 through the cathode electrode CE.

The cathode electrode CE may be configured to be substantially transparent or translucent to satisfy a selectable light transmittance. In embodiments, the cathode electrode CE may include at least one various transparent conductive materials such as indium tin oxide (ITO), indium zinc oxide (IZO), zinc oxide (ZnO), indium gallium zinc oxide (IGZO), and indium tin zinc oxide (ITZO). However, a material of the cathode electrode CE is not limited thereto.

The capping layer CPL may be disposed on the cathode electrode CE. The capping layer CPL may protect components under (or below) the capping layer CPL, such as the cathode electrode CE and the first to third light emitting elements LD1, LD2, and LD3 from external water, moisture, and the like within the spirit and the scope of the disclosure. The capping layer CPL may include at least one of a metal oxide such as silicon nitride, silicon oxide, silicon oxynitride, and aluminum oxide. However, a material of the capping layer CPL is not limited thereto.

The light functional layer LFL may be disposed on the capping layer CPL. The light functional layer LFL may include the second bank BNK2, the reflective layer RFL, a third passivation layer PSV3, first and second light conversion patterns CCP1 and CCP2, a light scattering pattern LSP, a low refractive layer LRL, and a color filter layer CFL.

The second bank BNK2 may be disposed on the capping layer CPL. The second bank BNK2 may overlap the first bank BNK1. The second bank BNK2 may have the second openings OP2 overlapping the first openings OP1.

The second bank BNK2 may be configured to include a light blocking material, thereby preventing light mixing between adjacent sub-pixels and the first to third sub-pixels SP1, SP2, and SP3. In embodiments, the second bank BNK2 may include an organic material. For example, the second bank BNK2 may include an organic insulating material such as acryl resin, epoxy resin, phenol resin, polyamide resin, and polyimide resin.

The reflective layer RFL may be disposed on side surfaces of the second bank BNK2 adjacent to the second openings OP2. The reflective layer RFL may be configured to reflect incident light, and thus light output efficiency may be improved. The reflective layer RFL may include a material suitable for reflecting light. The reflective layer RFL may include at least one among aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them. However, embodiments are not limited thereto.

It may be understood that the emission area EMA and the non-emission area NEMA for the first to third sub-pixels SP1, SP2, and SP3 are defined by the second bank BNK2. An area overlapping the second bank BNK2 may correspond to the non-emission area NEMA. An area overlapping the second openings OP2 of the second bank BNK2 may correspond to the emission area EMA.

The third passivation layer PSV3 may be disposed in the second openings OP2, on the capping layer CPL. The third passivation layer PSV3 may protect components disposed under (or below) the third passivation layer PSV3 and may provide a flat upper surface. The third passivation layer PSV3 may include a same material as one of the first and second passivation layers PSV1 and PSV2, but embodiments are not limited thereto.

The first and second light conversion patterns CCP1 and CCP2 and the light scattering pattern LSP may be disposed in the second openings OP2, on the third passivation layer PSV3.

The first and second light conversion patterns CCP1 and CCP2 and the light scattering pattern LSP may include color conversion particles and/or scattering particles. The color conversion particles may change a wavelength of incident light and convert the incident light into light of another color. The color conversion particles may scatter the incident light. In embodiments, the color conversion particles may be quantum dots. The scattering particles may scatter the incident light.

In embodiments, the first to third light emitting elements LD1, LD2, and LD3 may be configured to emit light of a blue color. In this case, the first light conversion pattern CCP1 may include first color conversion particles QD1 configured to convert the light of the blue color into light of a red color. The second light conversion pattern CCP2 may include second color conversion particles QD2 configured to convert the light of the blue color into light of a green color. The light scattering pattern LSP may include scattering particles SCT that scatter the light of the blue color to improve light output efficiency. Accordingly, the first to third sub-pixels SP1, SP2, and SP3 may be provided as a red sub-pixel, a green sub-pixel, and a blue sub-pixel, respectively. In embodiments, at least one of the first and second light conversion patterns CCP1 and CCP2 and the light scattering pattern LSP may further include color conversion particles that convert the light of the blue color into light of a white color.

In embodiments, the first to third light emitting elements LD1, LD2, and LD3 may be configured to emit the light of the red color, the green color, and the blue color, respectively. In this case, each of the first and second light conversion patterns CCP1 and CCP2 and the light scattering pattern LSP may include scattering particles SCT. As described above, according to a color of light emitted from the first to third light emitting elements LD1, LD2, and LD3, particles included in the first and second light conversion patterns CCP1 and CCP2 and the light scattering pattern LSP may be variously changed.

In embodiments, the first and second light conversion patterns CCP1 and CCP2 and the light scattering pattern LSP may be omitted.

The low refractive layer LRL may be disposed on the second bank BNK2, the reflective layer RFL, the first and second light conversion patterns CCP1 and CCP2, and the light scattering pattern LSP. The low refractive layer LRL may have a refractive index lower than that of the first and second light conversion patterns CCP1 and CCP2 and the light scattering pattern LSP. The low refractive layer LRL may be configured to refract or totally reflect corresponding light according to an incidence angle of light. The low refractive layer LRL may provide light passing through the first and second light conversion patterns CCP1 and CCP2 and the light scattering pattern LSP back to the first and second light conversion patterns CCP1 and CCP2 and the light scattering pattern LSP. Accordingly, light conversion efficiency and light scattering efficiency of the first and second light conversion patterns CCP1 and CCP2 and the light scattering pattern LSP may be improved. In embodiments, the low refractive layer LRL may be omitted in an area corresponding to the third sub-pixel SP3.

The color filter layer CFL may be disposed on the low refractive layer LRL. The color filter layer CFL may include first to third color filters CF1, CF2, and CF3, and light blocking patterns LBP.

The first to third color filters CF1, CF2, and CF3 may overlap the first and second light conversion patterns CCP1 and CCP2 and the light scattering pattern LSP, respectively. Each of the first to third color filters CF1, CF2, and CF3 may selectively transmit light of a desired wavelength range. In case that the first sub-pixel SP1 is a red sub-pixel, the first color filter CF1 may include a red color filter. In case that the second sub-pixel SP2 is a green sub-pixel, the second color filter CF2 may include a green color filter. In case that the third sub-pixel SP3 is a blue sub-pixel, the third color filter CF3 may include a blue color filter. The first to third color filters CF1, CF2, and CF3 may have a refractive index higher than that of the low refractive layer LRL. However, embodiments are not limited thereto, and the first to third color filters CF1, CF2, and CF3 may have a refractive index lower than or equal to that of the low refractive layer LRL.

The light blocking patterns LBP may be disposed between the first to third color filters CF1, CF2, and CF3. It may be understood that the emission area (or a light output area) EMA and the non-emission area NEMA for the first to third sub-pixels SP1, SP2, and SP3 are defined by the light blocking patterns LBP. An area overlapping the light blocking patterns LBP may correspond to the non-emission area NEMA. An area that does not overlap the light blocking patterns LBP may correspond to the emission area EMA.

In embodiments, the light blocking patterns LBP may include at least one of various types of light blocking materials. In embodiments, each of the light blocking patterns LBP may be provided in a form of multiple layers in which at least two color filters among the first to third color filters CF1, CF2, and CF3 overlap. For example, each of the light blocking patterns LBP may be formed by overlapping the first to third color filters CF1, CF2, and CF3. As another example, a light blocking pattern between the first and second color filters CF1 and CF2 among the light blocking patterns LBP may be formed as multiple layers in which the first and second color filters CF1 and CF2 overlap, and a light blocking pattern between the second and third color filters CF2 and CF3 among the light blocking patterns LBP may be formed as multiple layers in which the second and third color filters CF2 and CF3 overlap. A light blocking pattern between the first color filter CF1 and the third color filter CF3 of a neighboring pixel may be formed as multiple layers in which the first and third color filters CF1 and CF3 overlap. As described above, each of the first to third color filters CF1, CF2, and CF3 may extend to the non-emission area NEMA to form the light blocking patterns LBP.

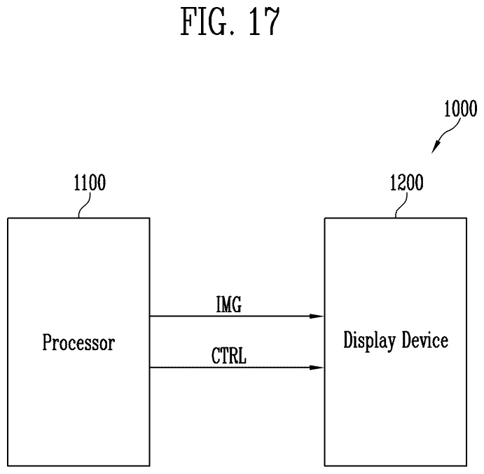

FIG. 17 is a block diagram illustrating a display system according to an embodiment.

Referring to FIG. 17, the display system 1000 may include a processor 1100 and a display device 1200.

The processor 1100 may perform various tasks and calculations. In embodiments, the processor 1100 may include an application processor, a graphics processor, a microprocessor, a central processing unit (CPU), and the like within the spirit and the scope of the disclosure. The processor 1100 may be connected to other components of the display system 1000 through a bus system to control the other components.

The processor 1100 may transmit image data IMG and a control signal CTRL to the display device 1200. The display device 1200 may display an image based on the image data IMG and the control signal CTRL. The display device 1200 may be configured similarly to the display device DD described with reference to FIG. 1. In this case, the image data IMG and the control signal CTRL may be provided as the input image data IMG and the control signal CTRL of FIG. 1, respectively.

The display system 1000 may include a computing system providing an image display function, such as a smart watch, a mobile phone, a smart phone, a portable computer, a tablet personal computer (PC), a watch phone, an automotive display, smart glasses, a portable multimedia player (PMP), a navigation device, and an ultra mobile personal computer (UMPC). The display system 1000 may include at least one of a head mounted display (HMD) device, a virtual reality (VR) device, a mixed reality (MR) device, and an augmented reality (AR) device.

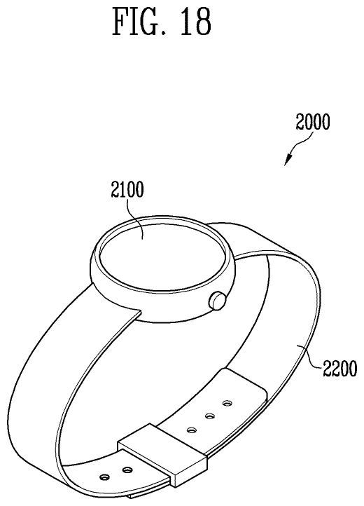

FIGS. 18 to 21 are schematic perspective views illustrating application examples of the display system of FIG. 17.

Referring to FIG. 18, the display system 1000 of FIG. 17 may be applied to a smart watch 2000 including a display unit 2100 and a strap unit 2200.

The smart watch 2000 may be a wearable electronic device. For example, the smart watch 2000 may have a structure in which the strap unit 2200 is mounted on a user's wrist. Here, the display system 1000 and/or the display device 1200 may be applied to the display unit 2100, and image data including time information may be provided to a user.

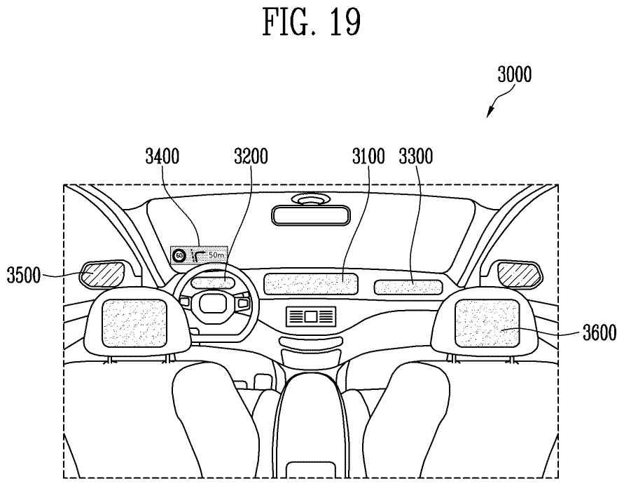

Referring to FIG. 19, the display system 1000 of FIG. 17 may be applied to an automotive display system 3000. Here, the automotive display system 3000 may include a computing system provided inside and/or outside a vehicle to provide image data.

For example, the display system 1000 and/or the display device 1200 may be applied to at least one of an infotainment panel 3100, a cluster 3200, a co-driver display 3300, a head-up display 3400, a side mirror display 3500, and a rear seat displays 3600 provided in a vehicle.

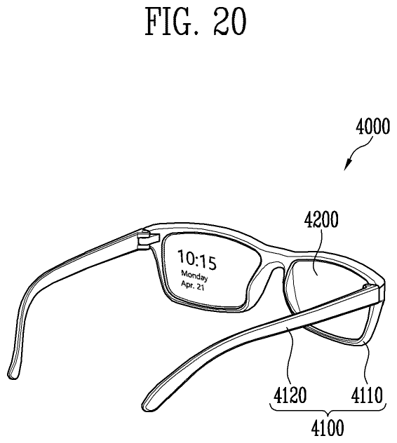

Referring to FIG. 20, the display system 1000 of FIG. 17 may be applied to smart glasses 4000. The smart glasses 4000 may be a wearable electronic device that may be worn on a user's head. For example, the smart glasses 4000 may be a wearable device for augmented reality.

The smart glasses 4000 may include a frame 4100 and a lens unit 4200. The frame 4100 may include a housing 4110 that supports the lens unit 4200 and a leg unit 4120 for the user to wear. The leg unit 4120 may be connected to the housing 4110 through a hinge and may be folded or unfolded relative to the housing 4110.

A battery, a touch pad, a microphone, a camera, and the like may be built in the frame 4100. A projector that outputs light, a processor that controls a light signal, and the like may be built in the frame 4100.

The lens unit 4200 may include an optical member that transmits or reflects light. For example, the lens unit 4200 may include glass, transparent synthetic resin, or the like within the spirit and the scope of the disclosure.

In order for user's eyes to recognize visual information, the lens unit 4200 may reflect an image by the light signal transmitted from the projector of the frame 4100 by a rear surface (for example, a surface of a direction facing the user's eyes) of the lens unit 4200. For example, the user may recognize visual information such as time and date displayed on the lens unit 4200. At this time, the projector and/or the lens unit 4200 may be a type of display device. The display device 1200 may be applied to the projector and/or the lens unit 4200.

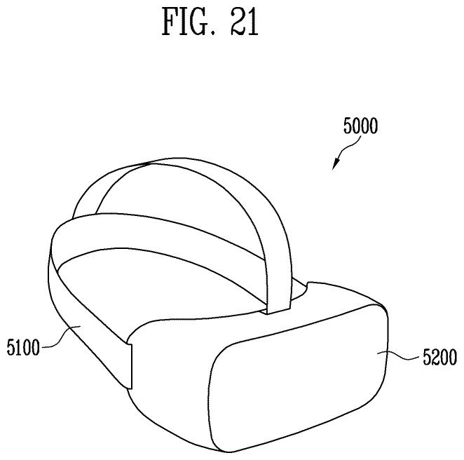

Referring to FIG. 21, the display system 1000 of FIG. 17 may be applied to a head mounted display device 5000.

The head mounted display device 5000 may be a wearable electronic device that may be worn on a user's head. For example, the head mounted display device 5000 may be a wearable device for virtual reality or mixed reality.

The head mounted display device 5000 may include a head mount band 5100 and a display device receiving case 5200. The head mount band 5100 may be connected to the display device receiving case 5200. The head mount band 5100 may include a horizontal band and/or a vertical band for fixing the head mounted display device 5000 to a user's head. The horizontal band may be configured to surround a side portion of the user's head, and the vertical band may be configured to surround an upper portion of the user's head. However, embodiments are not limited thereto. For example, the head mount band 5100 may be implemented in a form of a glasses frame, a helmet, or the like within the spirit and the scope of the disclosure.

The display device receiving case 5200 may receive the display system 1000 and/or the display device 1200.

Although described with reference to the above embodiments, it will be understood that those skilled in the art can variously modify and change the disclosure without departing from the spirit and scope of the disclosure described and in the claims below.

What is claimed is:

1. A light emitting element comprising:
a bonding electrode; and
a light emitting stack including a first semiconductor layer, an active layer, and a second semiconductor layer sequentially disposed each other on the bonding electrode, wherein
at least one protrusion structure is defined on an upper surface of the light emitting stack, and
the protrusion structure comprises:
a first protrusion protruding in a direction away from the bonding electrode and defining a groove concave in a direction facing the bonding electrode; and
a second protrusion protruding in a direction away from the bonding electrode in the groove of the first protrusion.

2. The light emitting element according to claim 1, wherein the second protrusion is spaced apart from an inner surface of the first protrusion defining the groove.

3. The light emitting element according to claim 1, wherein the second protrusion includes a (2-1)-th protrusion having a height about equal to a depth of the groove, and a (2-2)-th protrusion disposed on the (2-1)-th protrusion.

4. The light emitting element according to claim 3, wherein the (2-2)-th protrusion has a substantially cone shape.

5. The light emitting element according to claim 1, wherein the protrusion structure and the second semiconductor layer are integral.

6. The light emitting element according to claim 5, wherein the first protrusion and the second protrusion are integral.

7. The light emitting element according to claim 1, wherein the protrusion structure includes a first protrusion structure disposed at a center of the upper surface of the light emitting stack in a plan view.

8. The light emitting element according to claim 1, wherein
the protrusion structure includes a plurality of second protrusion structures, and
the plurality of second protrusion structures are disposed symmetrically with respect to a center of the upper surface of the light emitting stack in a plan view.

9. The light emitting element according to claim 1, wherein
the first semiconductor layer has a first polarity, and
the second semiconductor layer has a second polarity different from the first polarity.

10. The light emitting element according to claim 9, wherein
the second semiconductor layer includes a first doping portion and a second doping portion sequentially defined on the active layer, and
a first average doping concentration of a dopant in the first doping portion is greater than a second average doping concentration of a dopant in the second doping portion.

11. A display device comprising:
a light emitting element connected between an anode electrode and a cathode electrode,
wherein the light emitting element comprises:
a bonding electrode; and
a light emitting stack including a first semiconductor layer, an active layer, and
a second semiconductor layer sequentially disposed each other on the bonding electrode,
at least one protrusion structure is defined on an upper surface of the light emitting stack, and
the protrusion structure comprises:
a first protrusion protruding in a direction away from the bonding electrode and defining a groove concave in a direction facing the bonding electrode; and
a second protrusion protruding in a direction away from the bonding electrode in the groove of the first protrusion.

12. The display device according to claim 11, wherein the second protrusion is spaced apart from an inner surface of the first protrusion defining the groove.

13. The display device according to claim 11, wherein the second protrusion includes a (2-1)-th protrusion having a height about equal to a depth of the groove, and a (2-2)-th protrusion disposed on the (2-1)-th protrusion.

14. The display device according to claim 13, wherein the (2-2)-th protrusion has a substantially cone shape.

15. The display device according to claim 11, wherein the protrusion structure and the second semiconductor layer are integral.

16. The display device according to claim 15, wherein the first protrusion and the second protrusion are integral.

17. The display device according to claim 11, wherein the protrusion structure includes a first protrusion structure disposed at a center of the upper surface of the light emitting stack in a plan view.

18. The display device according to claim 11, wherein
the protrusion structure includes a plurality of second protrusion structures, and
the plurality of second protrusion structures are disposed symmetrically with respect to a center of the upper surface of the light emitting stack in a plan view.

19. The display device according to claim 11, wherein the bonding electrode is disposed on the anode electrode and is electrically connected to the anode electrode.

20. The display device according to claim 19, wherein the cathode electrode is disposed on the anode electrode to face the anode electrode, and covers the upper surface of the light emitting stack defining the protrusion structure.
